(19) United States
(12) Patent Application Publication
(10) Pub. No.: US 2022/0147273 A1
(43) Pub. Date: May 12, 2022

(54) MEMORY CONTROLLER AND MEMORY SYSTEM

(71) Applicant: SK hynix Inc., Gyeonggi-do (KR)

(72) Inventors: Won Gyu SHIN, Gyeonggi-do (KR); Ju Yeong YOON, Gyeonggi-do (KR)

(21) Appl. No.: 17/225,497

(22) Filed: Apr. 8, 2021

(30) Foreign Application Priority Data
Nov. 10, 2020 (KR) 10-2020-0149166

(51) Int. Cl. G06F 3/06; G06F 9/38

(52) U.S. Cl. CPC G06F 3/0659; G06F 3/0653; G06F 9/3836; G06F 3/0625; G06F 3/0679; G06F 3/0623

(57) ABSTRACT

A memory system includes: a memory; and a memory controller suitable for issuing a command to the memory and performing a power throttling operation based on a number of read commands and a number of write commands that are issued to the memory for a predetermined time, and ratios of ‘1’ and ‘0’ of write data.

### CROSS-REFERENCE TO RELATED APPLICATIONS

The present application claims priority to Korean Patent Application No. 10-2020-0149166, filed on Nov. 10, 2020, which is incorporated herein by reference in its entirety.

### BACKGROUND

### 1. Field

Various embodiments of the present invention relate to a memory system including a memory and a memory controller for controlling the memory.

### 2. Description of the Related Art

Recently, research on the next-generation memories to replace Dynamic Random Access Memories (DRAM) and flash memories has been actively conducted. Among these next-generation memories is a resistive memory using a material that can switch between at least two different resistance states by rapidly changing the resistance according to an applied bias, that is, a variable resistance material. Representative examples of the resistive memory include a Phase-Change Random Access Memory (PCRAM), a Resistive Random Access Memory (PRAM), a Magnetic Random Access Memory (MRAM), a Ferroelectric Random Access Memory (FRAM), and the like.

In particular, the resistive memory may form a memory cell array in a cross point array structure. The cross-point array structure may refer to a structure in which a plurality of lower electrodes (e.g., a plurality of row lines (word lines)) and a plurality of upper electrodes (e.g., a plurality of column lines (bit lines)) cross each other and a memory cell in which a variable resistance element and a selection element are coupled in series is positioned at each cross point.

Power throttling is applied to resistive memories. Power throttling may be performed in such a manner that issuing of a command to the resistive memory is blocked and accordingly the power consumption and temperature of the resistive memory is lowered, when the power consumption of the resistive memory exceeds a threshold value.

### SUMMARY

Various embodiments of the present invention are directed to providing a memory system that performs more efficient power throttling.

In accordance with an embodiment of the present invention, a memory system includes: a memory; and a memory controller suitable for issuing a command to the memory and performing a power throttling operation based on a number of read commands and a number of write commands that are issued to the memory for a predetermined time, and ratios of ‘1’ and ‘0’ of write data.

In accordance with another embodiment of the present invention, a memory controller includes: a host interface suitable for communicating with a host; a scheduler suitable for scheduling an order of processing requests of the host; a command generator suitable for generating commands to be applied to a memory according to the order scheduled by the scheduler; a memory interface suitable for transferring the commands generated by the command generator to the memory; and a power throttling controller suitable for controlling power throttling of the memory based on a number of read commands and a number of write commands that are issued from the memory interface to the memory for a predetermined time, and ratios of ‘1’ and ‘0’ of write data.

In accordance with still another embodiment of the present invention, a memory system includes: a memory suitable for performing read and write operations; and a controller suitable for performing a power throttling operation on the memory when power consumption by the read and write operations when a predetermined amount of time becomes greater than a threshold, wherein the power consumption by the write operation is as follows: [a ratio of ‘1’ data in write data]*A+[a ratio of ‘0’ data in the write data]*B+[a ratio of ‘no write’ data in the write data]*C, where A is greater than B, which is greater than C, and the write data is a target of the write operation, and wherein A, B, and C are amounts of consumed power measured respectively when the write data is all ‘1’, when the write data is all ‘0’ and when the write data is all ‘no write’ data.

### BRIEF DESCRIPTION OF THE DRAWINGS

FIG. 1 is a block diagram illustrating a memory system 100 in accordance with an embodiment of the present invention.

FIG. 2 is a block diagram illustrating a read-modify-write circuit 121.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

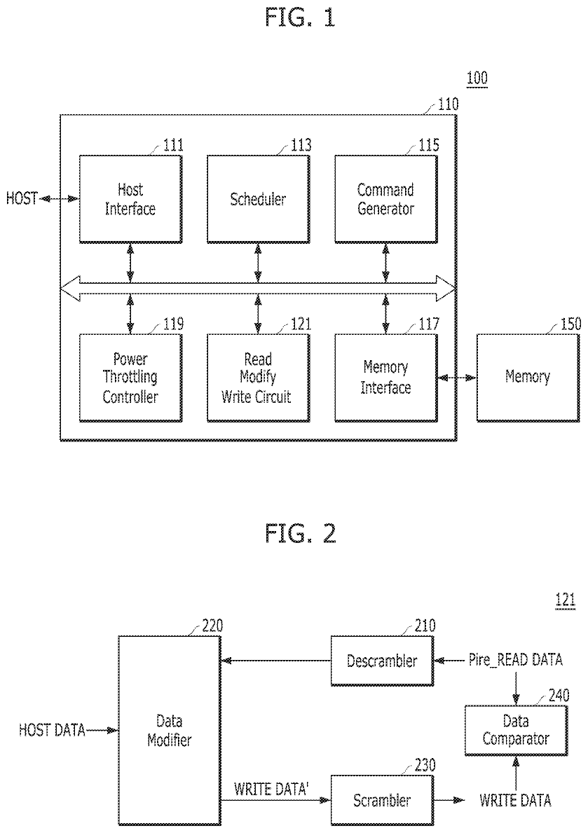

FIG. 1 is a block diagram illustrating a memory system 100 in accordance with an embodiment of the present invention.

Referring to FIG. 1, the memory system 100 may include a memory controller 110 and a memory 150.

The memory controller 110 may control various operations of the memory 150, for example, a read operation and a write operation, according to a request of the host HOST.

The memory 150 may perform diverse operations commanded by the memory controller 110. The memory 150 may be one among all types of memories. For example, the memory 150 may be one among resistive memories, such as Phase-Change Random Access Memory (PCRAM), Resistive Random Access Memory (RRAM), Magnetic Random Access Memory (MRAM), and Ferroelectric Random Access Memory (FRAM). Furthermore, the memory 150 may not be a resistive memory but may be one among NAND Flash and DRAM. During the write operation of the memory 150, current consumption may be different when data of ‘1’ is written and when data of ‘0’ is written. For example, when ‘1’ is written into the memory 150, more current may be consumed than when ‘0’ is written. Also, when write data is the same as the data already stored, the memory 150 may not write the data. For example, when 128 bits among the 256 bits of write data transferred to the memory 150 are the same as the data that are already stored in the memory 150 during a write operation, the memory 150 may write only the other 128 bits of the write data that are different from the data already stored the memory 150.

The memory controller 110 may include a host interface 111, a scheduler 113, a command generator 115, a memory interface 117, a power throttling controller 119, and a read-modify-write circuit 121.

The host interface 111 may be provided for an interface between the memory controller 110 and a host HOST. Through the host interface 111, requests, addresses and data corresponding to the requests may be received from the host and processing results of the requests may be transferred to the host. The host interface 111 may support one among PCI-EXPRESS (PCIe), Cache Coherent Interconnect for Accelerators (CCIX), Dual In-Line Memory Module (DIMM) and other diverse types of interfacing standards.

The scheduler 113 may schedule the operations to be performed by the memory 150. For example, when five requests A, B, C, D and E are received from the host through the host interface 111, the scheduler 113 may schedule the order of the requests A, B, C, D and E to be processed by the memory 150. When the power throttling controller 119 determines that power throttling needs to be performed, the scheduler 113 may temporarily stop the scheduling operation so that no command is issued to the memory 150 during the power throttling.

The command generator 115 may generate commands to be applied to the memory 150 according to the order of the operations corresponding to the requests scheduled by the scheduler 113.

The memory interface 117 may be provided for an interface between the memory controller 110 and the memory 150. The memory interface 117 may transfer a command generated by the command generator 115 and an address corresponding to the command to the memory 150 and transfer/receive data to/from the memory 150.

The read-modify-write circuit 121 may generate write data by using data read from the memory 150 and data transferred from the host HOST. A Read-modify-write (RMW) operation may be an operation of generating write data by reading data from the memory 150 and replacing a part of the read data with the data transferred from the host. It is illustrated in FIG. 1 that the memory controller 110 supports the read-modify-write operation and includes the read-modify-write circuit 121 for this. However, when the memory controller 110 does not support the read-modify-write operation, the read-modify-write circuit 121 may be omitted from the memory controller 110.

FIG. 2 is a block diagram illustrating the read-modify-write circuit 121. Referring to FIG. 2, the read-modify-write circuit 121 may include a descrambler 210, a data modifier 220, a scrambler 230, and a data comparator 240.

The descrambler 210 may descramble pre-read data READ DATA that are read from the memory 150 for a read-modify-write operation. The descrambling may be performed because the pre-read data are the data scrambled by the scrambler 230 before being written into the memory 150. The data modifier 220 may generate write data’ based on the data descrambled by the descrambler 210 and the write data HOST DATA transferred from the host HOST. The scrambler 230 may generate write data to be written into the memory 150 by scrambling the write data WRITE DATA’. Herein, scrambling may refer to encrypting data by using an encryption key for security, and descrambling may refer to decrypting the encrypted data by using the same encryption key, that is, an operation opposite to the scrambling operation. The data comparator 240 may compare the pre-read data with the write data to determine a part, within the write data WRITE DATA, to be actually written into the memory 150 during a write operation. Particular types of memories may not write the data that are the same as the already stored data but write only the data that are different from the already stored data. The data already stored in the memory 150 may be compared with the new data WRITE DATA to be stored through the comparison operation of the data comparator 240 to determine the part to be actually written into the memory 150 within the data WRITE DATA. Although FIG. 2 illustrates the read-modify-write circuit 121 including a scrambler 230 and a descrambler 210 for security, the read-modify-write circuit 121 may not include the scrambler 230 and the descrambler 210.

Referring back to FIG. 1, the power throttling controller 119 may control a power throttling operation. The power throttling operation is an operation of controlling the issuance of commands to the memory 150 such that the power consumption of the memory 150 does not exceed a power limit for a predetermined time. When the power consumption of the memory 150 is likely to exceed the power limit for a predetermined time, the power throttling controller 119 may stop the scheduling operation of the scheduler 113 so that the memory controller 110 does not issue a command to the memory 150 for a while. The power throttling controller 119 needs to measure the power consumption of the memory 150 for a predetermined time. The number of read commands and the number of write commands that are issued to the memory 150 for a predetermined time, the ratio of ‘1’ and ‘0’ of the write data, and the ratio of ‘no write’ data may be used to measure the power consumption. Herein, ‘1’ data may be called ‘set’ data, and ‘0’ data may be called ‘reset’ data.

The power throttling controller 119 may regard, as a substantially constant value, read power consumed by the memory 150 during a read operation. That is, the power throttling controller 119 may assume that a predetermined amount of power is consumed in the memory 150 whenever a read command is applied to the memory 150. This is because the ratios of ‘1’ and ‘0’ of the read data hardly affects the power consumption of the read operation of the memory 150. Hereinafter, the read power per read operation of the memory 150 is approximately 200 mW.

The power throttling controller 119 may take the write data into consideration to measure the write power consumed by the memory 150 during a write operation. This is because the ratios of ‘1’ and ‘0’ and the ratio of ‘no data’ of the write data greatly affect the power consumption of the write operation of the memory 150. Herein, the ratios of ‘1’ and ‘0’ of the write data may mean the ratios of ‘1’ and ‘0’ of the data to be written into the memory 150 to the total amount of data to be a written into the memory, so the ratios of ‘1’ and ‘0’ may be determined based on the data WRITE DATA scrambled by the scrambler 230. Also, the ratio of ‘no write’ data may be determined by the data comparator 240. For example, in one write operation, the ratio of ‘1’ may be approximately 30%, and the ratio of ‘0’ may be approximately 20%, and the ‘no write’ data may be approximately 50%.

The power consumption per write operation of the memory 150 may be calculated as shown in Equation 1.

Power consumption of write operation=[Ratio of ‘1’ data in write data*A]+[Ratio of ‘0’ data in write data*B]+[Ratio of ‘no write’ data in write data*C] [Equation 1]

Here, A>B>C, and A, B, and C may be real numbers of 0 or greater. A, B, and C may be amounts of consumed power measured respectively when the write data is all ‘1’, when the write data is all ‘0’ and when the write data is all ‘no write’ data. A, B, and C may be heuristically measured in advance. Hereinafter, A is 800 mW, and B is 200 mW, and C is 100 mW.

Referring to Equation 1, it may be seen that as the ratio of ‘no write’ data becomes higher and the ratio of ‘0’ data becomes higher, power consumption of the write operation of the memory 150 becomes less. If the ratio of ‘1’ is 30%, and the ratio of ‘0’ is 20%, and the ‘no write’ data is 50% in the write operation, the power consumption of the write operation becomes 0.3*800 mW+0.2*200 mW+0.5*100 mW=330 mV according to Equation 1.

In an embodiment, there may be a case that the ratio of ‘no write’ of the write data cannot be measured. When the read-modify-write circuit 121 does not exist in the memory controller 110 because the read-modify-write operation is not supported, it is impossible for the memory controller 110 to determine the ratio of ‘no write’. In this case, it may be that all write data are written into the memory 150 during a write operation, and the power throttling controller 119 may determine the power consumption of the write operation of the memory 150 in consideration of only the ratios of ‘1’ and ‘0’ of the write data. In this case, the power consumption per write operation of the memory 150 may be calculated as shown in the following Equation 2.

Power consumption of write operation=[Ratio of ‘1’ data in write data*A]+[Ratio of ‘0’ data in write data*B] [Equation 2]

It may be seen from Equation 2 that the higher the ratio of ‘0’ data, the less power consumption of the write operation of the memory 150 becomes. When, in a write operation, the ratio of ‘1’ is 60% and the ratio of ‘0’ is 40%, the power consumption of the write operation may be 560 mV (0.6*800 mW+0.4*200 mV=560 mV) according to Equation 2.

It is assumed that a predetermined time which is a reference for power throttling of the memory 150, that is, a time window, is 1 μs (1 μs=1000 ns), and that the power limit of the memory 150 is 7 W (7 W=7000 mW).

For example, when commands are applied to the memory 150 for 500 ns as follows: R->W (30%, 40%, 30%)->R->R->W (10%, 30%, 60%)->W (30%, 20%, 50%)->W (30%, 50%, 20%)->R->W (10%, 60%, 20%)->W (40%, 20%, 40%)->R->R->W (30%, 10%, 60%), the power consumption of the memory 150 may be examined. Here, R may represent a read command and W may represent a write command. Also, % numbers in the parentheses may represent the ratio of ‘1’ data, the ratio of ‘0’ data, and the ratio of ‘no write’ data, sequentially. When the power throttling controller 119 calculates the power consumption of the memory 150, it is 3380 mW (=200 mW+350 mW+200 mW+200 mW+200 mW+330 mW+360 mW+200 mW+220 mW+400 mW+200 mW+200 mW+320 mW). Since the memory 150 consumes 3380 mW of power for 500 ns, the memory 150 can further consume 3620 mW of power during the remaining 500 ns of the time window without causing the power throttling. In other words, the memory system 100 may operate without causing power throttling based on the assumption that the power consumption trend is repeated with a similar pattern.

When a power throttling controller is designed without consideration of the ratio of write data as an example to be compared with the present disclosure, the power consumption of a memory during a single write operation may be the maximum power (=800 mW). In other words, the power of the write operation has to be measured by assuming the worst case of the write operation, during which the ratio of ‘1’ of the write data is 100%. In this case, when the power consumption of the memory is measured with the same command sequence and the same time (i.e., 500 ns), it becomes 6800 mW (=200 mW+800 mW+200 mW+200 mW+800 mW+800 mW+800 mW+200 mW+800 mW+800 mW+200 mW+200 mW+800 mW). In this case, since 6800 mW of power is already consumed for 500 ns, power throttling may occur in which no command is applied from the memory controller to the memory for the remaining 500 ns.

Since the power throttling controller 119 figures out not only the number of read commands and the number of write commands that are issued to the memory 150, but also the power consumption of the memory 150 in consideration of the ratio of write data, it may measure the power consumption accurately. Therefore, power throttling may be controlled more efficiently.

According to the embodiment of the present invention, power throttling may be controlled more efficiently in a memory system.

While the present invention has been described with respect to the specific embodiments, it will be apparent to those skilled in the art that various changes and modifications may be made without departing from the spirit and scope of the invention as defined in the following claims.

What is claimed is:

1. A memory system, comprising:
a memory; and
a memory controller suitable for issuing a command to the memory and performing a power throttling operation based on a number of read commands and a number of write commands that are issued to the memory for a predetermined time, and ratios of ‘1’ and ‘0’ of write data.

2. The memory system of claim 1, wherein the memory controller further uses a ratio of ‘no write’ data of the write data for the power throttling operation.

3. The memory system of claim 2, wherein the memory controller supports a read-modify-write (RMW) operation.

4. The memory system of claim 1, wherein the memory controller includes:
a host interface suitable for communicating with a host;
a scheduler suitable for scheduling an order of processing requests of the host;
a command generator suitable for generating commands to be applied to the memory according to the order scheduled by the scheduler;
a memory interface suitable for transferring the commands generated by the command generator to the memory; and
a power throttling controller suitable for controlling the power throttling operation.

5. The memory system of claim 4,
wherein the memory controller further includes a data scrambler suitable for scrambling data, and
wherein the power throttling controller determines the ratios of ‘1’ and ‘0’ of the write data based on a scrambling result of the data scrambler.

6. The memory system of claim 4, wherein the memory controller further includes:
a read-modify-write circuit suitable for generating the write data based on data read from the memory and data transferred from the host; and
the read-modify-write circuit calculates the ratio of ‘no write’ data of the write data by comparing the data read from the memory with the data transferred from the host.

7. The memory system of claim 6, wherein the power throttling controller further uses the ratio of ‘no write’ data of the write data, which is determined by the read-modify-write circuit.

8. The memory system of claim 2, wherein the memory controller calculates power consumption of each of the write operations based on an equation of [a ratio of ‘1’ data of write data*A]+[a ratio of ‘0’ data of write data*B]+[a ratio of ‘no write’ data of write data*C], where A>B>C, and A, B and C are real numbers of 0 or greater.

9. A memory controller, comprising:
a host interface suitable for communicating with a host;
a scheduler suitable for scheduling an order of processing requests of the host;
a command generator suitable for generating commands to be applied to a memory according to the order scheduled by the scheduler;
a memory interface suitable for transferring the commands generated by the command generator to the memory; and
a power throttling controller suitable for controlling power throttling of the memory based on a number of read commands and a number of write commands that are issued from the memory interface to the memory for a predetermined time, and ratios of ‘1’ and ‘0’ of write data.

10. The memory controller of claim 9, wherein the power throttling controller further uses a ratio of ‘no write’ data of the write data.

11. The memory controller of claim 9,
further comprising a data scrambler suitable for scrambling data, and
wherein the power throttling controller determines the ratios of ‘1’ and ‘0’ of the write data based on a scrambling result of the data scrambler.

12. The memory controller of claim 9, further comprising:
a read-modify-write circuit suitable for generating the write data based on data read from the memory and data transferred from the host; and
the read-modify-write circuit calculates the ratio of ‘no write’ data of the write data by comparing the data read from the memory with the data transferred from the host.

13. The memory controller of claim 12, wherein the power throttling controller further uses the ratio of ‘no write’ data of the write data which is determined by the read-modify-write circuit.

14. The memory controller of claim 10, wherein the power throttling controller calculates a power consumption of each of the write operations based on an equation of [a ratio of ‘1’ data of write data*A]+[a ratio of ‘0’ data of write data*B]+[a ratio of ‘no write’ data of write data*C], where A>B>C, and A, B and C are real numbers of 0 or greater.

15. A memory system comprising:
a memory suitable for performing read and write operations; and
a controller suitable for performing a power throttling operation on the memory when power consumption by the read and write operations when a predetermined amount of time becomes greater than a threshold,
wherein the power consumption by the write operation is as follows:
[a ratio of ‘1’ data in write data]*A+[a ratio of ‘0’ data in the write data]*B+[a ratio of ‘no write’ data in the write data]*C, where A is greater than B, which is greater than C, and the write data is a target of the write operation, and
wherein A, B, and C are amounts of consumed power measured respectively when the write data is all ‘1’, when the write data is all ‘0’ and when the write data is all ‘no write’ data.

16. The memory system of claim 15, wherein the ratio of ‘no write’ data in the write data is zero (0).

17. The memory system of claim 15, wherein the power consumption by the read operation is predetermined.
